(19) United States
(12) Patent Application Publication
(10) Pub. No.: US 2011/0136450 A1
(43) Pub. Date: Jun. 9, 2011

(54) POWER CIRCUIT AND RADIO COMMUNICATION CIRCUIT USING SAME AND METHOD OF OPERATING A CIRCUIT

(75) Inventors: Minoru Hirahara, Kawasaki (JP); Seiji Miyoshi, Kawasaki (JP); Yoshito Koyama, Kawasaki (JP); Hironobu Hongo, Kawasaki (JP); Katsutoshi Ishidoh, Kawasaki (JP)

(73) Assignee: FUJITSU LIMITED, Kawasaki (JP)

(21) Appl. No.: 12/720,037

(22) Filed: Mar. 9, 2010

(30) Foreign Application Priority Data
Dec. 3, 2009 (JP) 2009-060002

(51) Int. Cl. H04B 1/04; H04B 1/10; H03L 5/00

(52) U.S. Cl. 455/127.1; 327/551; 327/307

(57) ABSTRACT

A power circuit and method thereof are provided. The power circuit includes an output circuit having an alternating current-coupling element and that supplies an output signal of the output circuit to an amplifier as a driving voltage. The power circuit includes an envelope signal-extracting unit extracting an envelope signal from a carrier wave, a simulation signal-waveform generating unit generating a simulation signal including a fluctuation component occurring when the envelope signal is transmitted to the output circuit, a fluctuation component-extracting unit extracting the fluctuation component included in the simulation signal, and an inverted component-generating unit generating an inverted component obtained by performing phase inversion for the fluctuation component, where the fluctuation component occurring in the output circuit is canceled out through the inverted component.

### CROSS-REFERENCE TO RELATED APPLICATIONS

This application is based upon and claims the benefit of priority of the prior Japanese Patent Application No. 2009-60002, filed on Mar. 12, 2009, the entire contents of which are incorporated herein by reference.

### BACKGROUND

1. Field

Embodiments described herein relate to a power circuit and method thereof based on an envelope tracking system and a radio communication circuit including the power circuit.

2. Description of the Related Art

A radio communication device may include a power circuit configured to output a voltage which is always constant and/or a power circuit configured to output a time-varying voltage.

A reduction in the power consumption of the power circuit can lead to a reduction in the power consumption of the radio communication device. Therefore, various improvements have been made to reduce the power loss of the power circuit.

For example, in a power circuit configured to output a step-like voltage, the driving voltage of an amplifier is changed in a step-like manner in synchronization with the amplitude of an input signal transmitted to the amplifier so that the power loss of the amplifier is reduced. Of the elements of the power circuit, the amplifier consumes a relatively large amount of power. Therefore, reducing the power loss of the amplifier is effective at reducing power consumed by the radio communication device including the power circuit.

A tracking system using an envelope signal has been proposed to reduce the power consumption of the power circuit.

As the power circuit based on the envelope tracking system, circuits including an amplifier configured to generate the modulation component of an envelope signal have been achieved. Since the envelope signal falls within a high-frequency band corresponding to a few tens of MHz, a high-speed operational amplifier should be used for the power circuit.

FIG. 1 illustrates a radio communication circuit including a power circuit achieved based on a typical envelope tracking system.

The power circuit based on the typical envelope tracking system includes a radio frequency (RF) amplifier 1 and an envelope signal-output unit 2. Further, a radio communication circuit including the power circuit based on the typical envelope tracking system includes a transmission amplifier 3 provided as the final stage of the radio communication device and a main signal-output unit 4 configured to output a main signal transmitted to the transmission amplifier 3. An antenna 5 is connected to the transmission amplifier 3.

An envelope signal transmitted from the envelope signal-output unit 2 is amplified through the RF amplifier 1 and is supplied to the transmission amplifier 3 as a driving voltage having a waveform similar to that of the envelope signal.

The main signal is transmitted from the main signal-output unit 4 to the transmission amplifier 3. The transmission amplifier 3 is driven by the driving voltage supplied from the RF amplifier 1 and outputs a radio communication signal in synchronization with the envelope signal.

The main signal-output unit 4 is configured to output the main signal which shall be transmitted via the transmission amplifier 3. When the radio communication device is provided as a mobile phone-base station, for example, the main signal represents a voice signal, an image signal, and so forth that are used to communicate with a mobile phone used in the communication area of the mobile phone-base station.

Since the radio communication circuit illustrated in FIG. 1 allows for applying the driving voltage corresponding to the main signal to the transmission amplifier 3, the power loss of the transmission amplifier 3 can be reduced.

In the above-described radio communication circuit, however, a power loss occurs in the RF amplifier 1 configured to generate the driving voltage of the transmission amplifier 3. In the RF amplifier 1, the difference between the driving voltage and an output voltage leads to the power loss. Therefore, even though the radio communication circuit illustrated in FIG. 1 performs envelope tracking to reduce the power loss of the transmission amplifier 3, the power loss of the RF amplifier 1 is increased. Accordingly, a reduction of the power loss of the entire circuit has not been achieved.

### SUMMARY

According to an aspect of the invention, a power circuit and method thereof are provided. The power circuit includes an output circuit including an alternating current-coupling element and that supplies an output signal of the output circuit to an amplifier as a driving voltage is provided, where the power circuit includes an envelope signal-extracting unit configured to extract an envelope signal from a carrier wave, a simulation signal-waveform generating unit configured to generate a simulation signal including a fluctuation component occurring when the envelope signal is transmitted to the output circuit, a fluctuation component-extracting unit configured to extract the fluctuation component included in the simulation signal, and an inverted component-generating unit configured to generate an inverted component obtained by performing phase inversion for the fluctuation component, wherein the fluctuation component occurring in the output circuit is canceled out through the inverted component.

The aspect and advantages of the invention will be realized and attained by means of the elements and combinations particularly pointed out in the claims.

It is to be understood that both the foregoing general description and the following detailed description are exemplary and explanatory and are not restrictive of the invention, as claimed.

Additional aspects and/or advantages will be set forth in part in the description which follows and, in part, will be apparent from the description, or may be learned by practice of the invention.

### BRIEF DESCRIPTION OF THE DRAWINGS

These and/or other aspects and advantages will become apparent and more readily appreciated from the following description of the embodiments, taken in conjunction with the accompanying drawings of which:

FIG. 1 illustrates a diagram of a radio communication circuit including a power circuit achieved based on a typical envelope tracking system;

FIG. 2 illustrates a diagram of a circuit configuration of a power circuit according to an embodiment of the present invention and a radio communication circuit including the power circuit;

FIG. 3A illustrates a diagram of a waveform of each of an envelope signal and a driving voltage of a power circuit of an embodiment and the radio communication circuit including the power circuit and the envelope signal transmitted from an envelope signal-output unit;

FIG. 3B illustrates a diagram of the waveform of each of the envelope signal and the driving voltage of the power circuit of an embodiment and the radio communication circuit including the power circuit and a driving voltage transmitted from an addition circuit when no inversion unit is provided;

FIG. 3C illustrates a diagram of the waveform of each of the envelope signal and the driving voltage of the power circuit of an embodiment and the radio communication circuit including the power circuit and a basic wave component subjected to a phase inversion through the inversion unit;

FIG. 3D illustrates a diagram of the waveform of each of the envelope signal and the driving voltage of the power circuit of an embodiment and the radio communication circuit including the power circuit and a driving voltage transmitted from the addition circuit when the inversion unit is provided;

FIG. 3E illustrates a diagram of the waveform of each of the envelope signal and the driving voltage of the power circuit of an embodiment and the radio communication circuit including the power circuit and an output signal transmitted from a high pass filter (HPF);

FIG. 3F illustrates a diagram of the waveform of each of the envelope signal and the driving voltage of the power circuit of an embodiment and the radio communication circuit including the power circuit and an output signal transmitted from a DC/DC converter;

FIG. 3G illustrates a diagram of the waveform of each of the envelope signal and the driving voltage of the power circuit of an embodiment and the radio communication circuit including the power circuit and a driving voltage transmitted from the addition circuit when the inversion unit is provided;

FIG. 4 illustrates a diagram of a circuit configuration of a power circuit according to an exemplary embodiment and a radio communication circuit including the power circuit;

FIG. 5 illustrates a diagram of the circuit configuration of a power circuit according to an embodiment of the present invention and a radio communication circuit including the power circuit;

FIG. 6 illustrates a diagram of the circuit configuration of a power circuit according to an exemplary embodiment and a radio communication circuit including the power circuit;

FIG. 7 illustrates a diagram of the circuit configuration of a power circuit according to an embodiment of the present invention and a radio communication circuit including the power circuit; and

FIG. 8 illustrates a diagram of the circuit configuration of a power circuit according to an exemplary embodiment and a radio communication circuit including the power circuit.

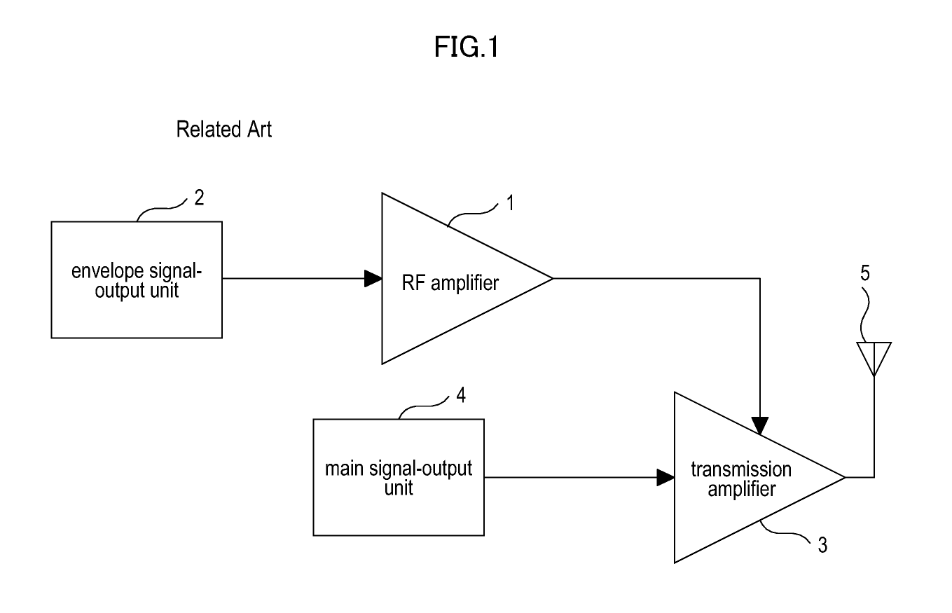

### DETAILED DESCRIPTION

Reference will now be made in detail to the embodiments, examples of which are illustrated in the accompanying drawings, wherein like reference numerals refer to the like elements throughout. The embodiments are described below to explain the present invention by referring to the figures.

Hereinafter, a power circuit according to an embodiment of the present invention and a radio communication circuit including the power circuit will be described. This application has been achieved to provide a power circuit configured to reduce the power loss based on the envelope tracking system and a radio communication circuit including the power circuit.

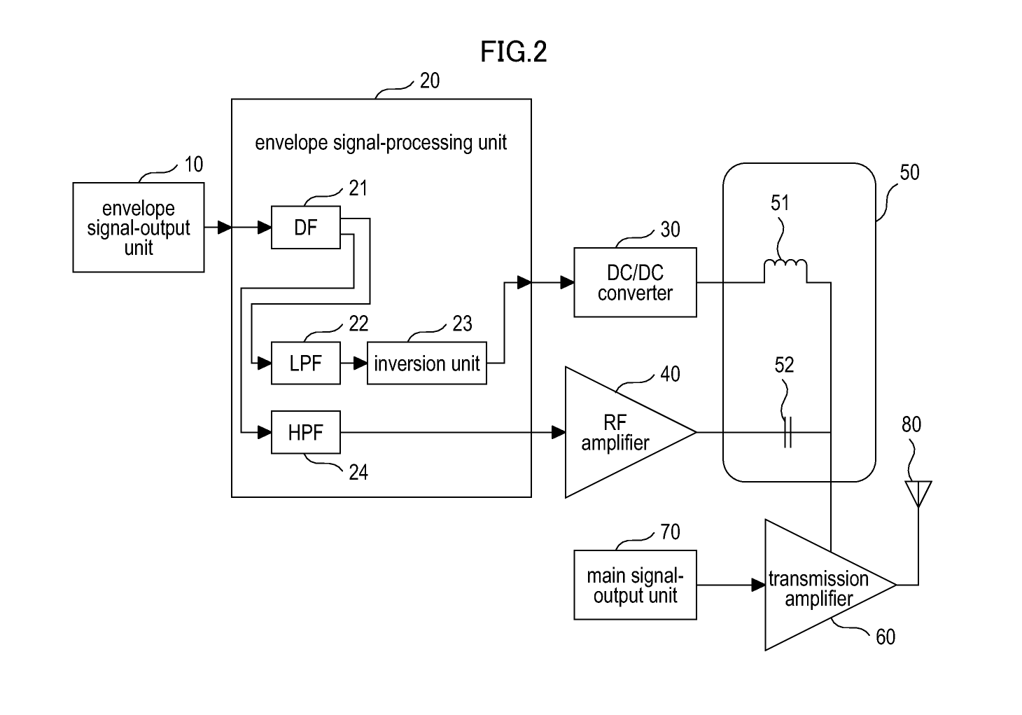

FIG. 2 illustrates a diagram illustrating a circuit configuration of a power circuit according to an embodiment of the present invention and a radio communication circuit including the power circuit.

The power circuit of an embodiment includes an envelope signal-output unit 10, an envelope signal-processing unit 20, a DC/DC converter 30, an RF amplifier 40, and an addition circuit 50.

The radio communication circuit including the power circuit of an embodiment includes the envelope signal-output unit 10, the envelope signal-processing unit 20, a DC/DC converter 30, an RF amplifier 40, an addition circuit 50, a transmission amplifier 60 functioning as a final stage of a radio communication device, and a main signal-output unit 70 configured to transmit a main signal transmitted to the transmission amplifier 60. An antenna 80 is connected to the transmission amplifier 60.

The envelope signal-output unit 10 extracts an envelope signal from a radio communication-carrier wave and externally transmits the envelope signal. The envelope signal is extracted by performing half-wave rectification for the carrier wave.

The envelope signal-processing unit 20 includes a digital filter (DF) 21, a low pass filter (LPF) 22, an inversion unit 23, and a high pass filter (HPF) 24.

The DF 21 is configured to generate a simulation signal having a waveform obtained when the envelope signal includes a fluctuation component (variation component) due to alternating-current coupling. The fluctuation component generated through the DF 21 corresponds to a fluctuation component occurring when the envelope signal is directly transmitted to the addition circuit 50. The waveform of the simulation signal is described in detail below.

The LPF 22 extracts a fluctuation component included in a signal transmitted from the DF 21 and externally transmits the fluctuation component. The LPF 22 may include, for example, an analog filter including a capacitor connected in parallel to an input end and a resistor connected in series with the input end. The cutoff frequency of the LPF 22 is set to remove a peak component included in a signal transmitted from the DF 21, where the peak component is a high-frequency component, so that only a fluctuation component which is a low-frequency component is allowed to pass.

The inversion unit 23 externally transmits an inverted component obtained by inverting the phase of the fluctuation component transmitted from the LPF 22 as an inverted signal. The above-described inversion unit 23 may include, for example, an operational amplifier-with-negative feedback having a grounded non-inverted input end.

The HPF 24 removes the fluctuation component included in a signal transmitted from the DF 21, and extracts a peak component from the above-described signal and externally transmits the peak component. The HPF 24 may include, for example, an analog filter including a resistor connected in parallel to the input end and a capacitor connected in series with the input end. The cutoff frequency of the HPF 24 is set to remove a fluctuation component included in a signal transmitted from the DF 21, where the fluctuation component is a low-frequency component, so that only a peak component which is a high-frequency component is allowed to pass.

The DC/DC converter 30 transforms and externally transmits the inverted signal transmitted from the inversion unit 23. The transformation performed through the DC/DC converter 30 is the voltage boosting and includes transformation performed in two operations, that is, transformation of the inverted signal and voltage boosting achieved by superimposing a direct voltage on the boosted inverted signal. Here, the transformation rate (boosting rate) of the inverted signal is set so that the transformation rate becomes equal to the amplification rate of the RF amplifier 40.

The RF amplifier 40 amplifies and externally transmits the peak component transmitted from the HPF 24. As described above, the amplification rate of the RF amplifier 40 is set to be equal to the transformation rate (boosting rate) of the inverted signal, which is attained in the DC/DC converter 30.

The addition circuit 50 is an output circuit that includes a coil 51 provided on the output side of the DC/DC converter 30 and a capacitor 52 provided on an output side of the RF amplifier 40, and that externally transmits a driving voltage which shall be transmitted to the transmission amplifier 60. The addition circuit 50 adds a voltage transmitted from the DC/DC converter 30 to a peak component amplified through the RF amplifier 40, and externally transmits the voltage and the peak component as the driving voltage of the transmission amplifier 60.

The coil 51 is provided to prevent the peak component transmitted from the RF amplifier 40 from being transferred to the DC/DC converter 30 and the capacitor 52 is provided to prevent the voltage transmitted from the DC/DC converter 30 from being transferred to the RF amplifier 40.

The main signal-output unit 70 is configured to externally transmit a main signal which shall be transmitted via the transmission amplifier 60. When the radio communication device is a mobile phone-base station, for example, the main signal represents a voice signal, an image signal, and so forth that are used to communicate with a mobile phone used in the communication area of the mobile phone-base station.

The transmission amplifier 60 is a radio communication amplifier provided in the final stage. The main signal is transmitted from the main signal-output unit 70 to the transmission amplifier 60 and a driving voltage transmitted from the addition circuit 50 is applied to the transmission amplifier 60. Then, the transmission amplifier 60 externally transmits a radio communication signal in synchronization with an envelope signal. The transmitted radio communication signal is externally transmitted from the antenna 80.

Here, when the radio communication device including the power circuit according to an embodiment and the radio communication circuit including the power circuit is a mobile phone-base station, a radio signal including a main signal is transmitted from the antenna 80 to a mobile phone used in the communication area of the base station.

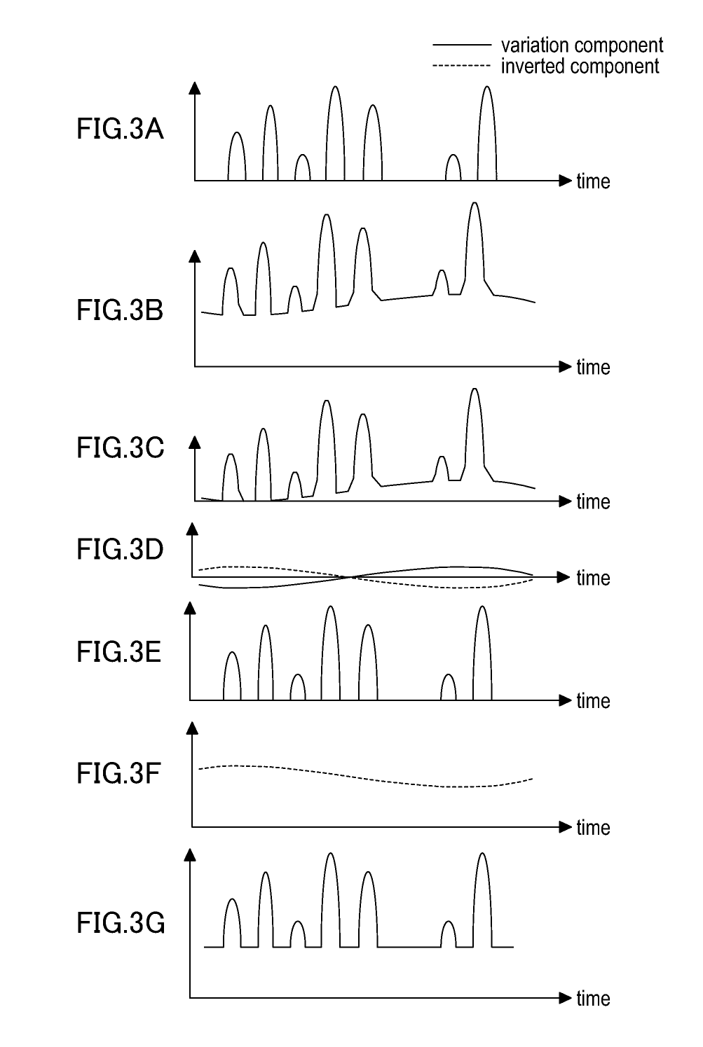

Each of FIGS. 3A, 3B, 3C, 3D, 3E, 3F and 3G is a diagram illustrating the waveform of each of an envelope signal and a driving voltage that are obtained through the power circuit according to an embodiment and the radio communication circuit including the power circuit. FIG. 3A illustrates an envelope signal transmitted from the envelope signal-output unit 10, FIG. 3B illustrates a driving voltage transmitted from the addition circuit 50 when the inversion unit 23 is not provided, FIG. 3C illustrates a simulation signal transmitted from the DF 21, FIG. 3D illustrates an output signal transmitted from the LPF 22 and a fluctuation component subjected to phase inversion through the inversion unit 23, FIG. 3E illustrates an output signal transmitted from the HPF 24, FIG. 3F illustrates an output signal transmitted from the DC/DC converter 30, and FIG. 3G illustrates a driving voltage transmitted from the addition circuit 50 when the inversion unit 23 is provided. In each of FIGS. 3A to 3G, the lateral axis represents time and the vertical axis represents the signal level (voltage value).

As illustrated in FIG. 3A, the envelope signal transmitted from the envelope signal-output unit 10 has a waveform attained by performing a half-wave rectification for a carrier wave.

The envelope signal transmitted from the envelope signal-output unit 10 is transmitted to the envelope signal-processing unit 20 and is digitally converted into a simulation signal (FIG. 3C) including a fluctuation component through the DF 21. As illustrated in FIG. 3C, the above-described simulation signal has a waveform including a fluctuation component occurring when the envelope signal is transmitted to the addition circuit 50. The fluctuation component included in the simulation signal corresponds to a fluctuation component occurring when the envelope signal is directly transmitted to the addition circuit 50.

The LPF 22 extracts a fluctuation component which is a low-frequency component from the simulation signal transmitted from the DF 21. The above-described fluctuation component has a waveform obtained by removing a peak component from the simulation signal as indicated by a solid line illustrated in FIG. 3D.

The inversion unit 23 performs phase inversion for the fluctuation component transmitted from the LPF 22 and externally transmits the fluctuation component. The inverted signal subjected to the phase inversion has a phase which is the inverse of the phase of the fluctuation component as indicated by a broken line illustrated in FIG. 3D.

The HPF 24 extracts a peak component which is a high-frequency component from the simulation signal transmitted from the DF 21. The extracted peak component has a waveform illustrated in FIG. 3E.

The DC/DC converter 30 boosts the inverted signal transmitted from the inversion unit 23 at the above-described specified transformation rate, superimposes the specified direct voltage on the inverted signal, and externally transmits the inverted signal. The amplitude of the inverted signal of the voltage for transmission is increased and the voltage for transmission has a waveform attained through the addition of a direct current component as illustrated in FIG. 3F. Further, the transformation rate (boosting rate) of the DC/DC converter 30 is set to be equivalent to the amplification rate of the RF amplifier 40 as described above.

Here, the capacitor 52 is connected to the output side of the RF amplifier 40, and the RF amplifier 40 and the transmission amplifier 60 are alternating-current coupled to each other. Therefore, when an output signal transmitted from the LPF 22 is directly transmitted to the DC/DC converter 30 and the inversion unit 23 is not provided, a fluctuation (fluctuation component) occurs in the basic wave component of the driving voltage as illustrated in FIG. 3B.

However, in the power circuit of an embodiment and the radio communication circuit including the power circuit, the inversion unit 23 externally transmits an inverted signal obtained by inverting the phase of a fluctuation component as indicated by the broken line illustrated in FIG. 3D.

Then, the DC/DC converter 30 boosts the inverted signal at the transformation rate equivalent to the amplification rate of the RF amplifier 40, superimposes the direct current component on the boosted inverted signal, and externally transmits the inverted signal as a voltage signal expressed by a waveform illustrated in FIG. 3F.

Further, when the addition circuit 50 adds the output signal transmitted from the DC/DC converter 30 to that of the RF amplifier 40, the inverted signal included in the output signal of the DC/DC converter 30 and the fluctuation component occurring in the addition circuit 50 cancel each other out.

Accordingly, the variation component of the output signal transmitted from the addition circuit 50 is cancelled out and a signal obtained by adding the peak component amplified through the RF amplifier 40 to the direct current component added by the DC/DC converter 30 is externally transmitted. The obtained signal has a waveform amplified to be similar to the waveform of an envelope signal transmitted from the envelope signal-output unit 10 as illustrated in FIG. 3G.

Thus, the power circuit of an embodiment and the radio communication circuit including the power circuit allow for canceling out the fluctuation component occurring in the addition circuit 50. Then, since the boosting rate of the DC/DC converter 30 is set to be equal to the amplification rate of the RF amplifier 40, the waveform (FIG. 3G) of the driving voltage transmitted from the addition circuit 50 becomes similar to the waveform (FIG. 3A) of the envelope signal transmitted from the envelope signal-output unit 10.

Accordingly, a driving voltage amplified to have a waveform similar to that of the envelope signal is transmitted to the transmission amplifier 60. Therefore, the transmission amplifier 60 can correctly perform the envelope tracking for the main signal and externally transmit a radio communication signal in synchronization with the envelope signal.

Thus, in an embodiment, the fluctuation component (variation component) occurring during the process of amplifying the envelope signal is removed and the direct voltage component of the driving voltage supplied to the transmission amplifier 60 is superimposed on the inverted signal during the transformation process performed through the DC/DC converter 30. Therefore, the driving voltage correctly amplified to have the waveform similar to that of the envelope signal transmitted from the envelope signal-output unit 10 can be supplied to the transmission amplifier 60. Accordingly, it becomes possible to provide a power circuit that can reduce the power loss based on the envelope tracking and a radio communication circuit including the power circuit.

In the above-described embodiment, the envelope signal-processing unit 20 is provided as an analog circuit. However, the envelope signal-processing unit 20 may be a digital circuit. In that case, each of the LPF 22, the inversion unit 23, and the HPF 24 may be a digital circuit.

Further, in the above-described embodiment, the addition circuit 50 includes the coil 51 and the capacitor 52. However, without being limited to the above-described embodiment, the addition circuit 50 may not include the coil 51 and the capacitor 52.

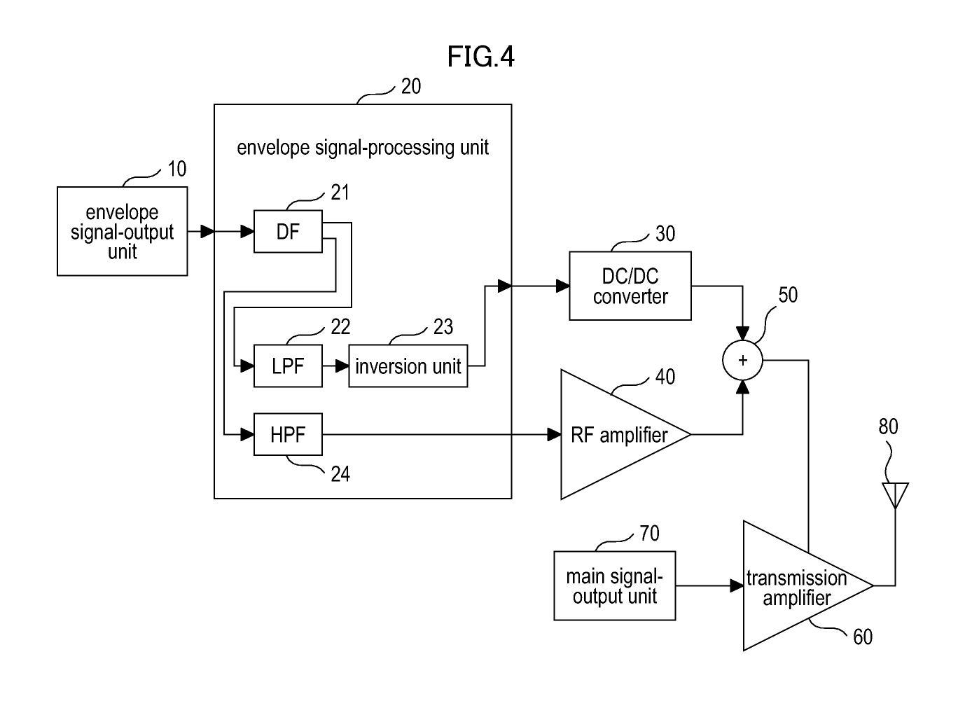

FIG. 4 illustrates a diagram illustrating the circuit configuration of a power circuit according to an exemplary modification of an embodiment and a radio communication circuit including the power circuit. The circuit configuration of the above-described modification is different from that illustrated in FIG. 2 in that the addition circuit 50 does not include the coil 51 and the capacitor 52 and is expressed as a block.

The addition circuit 50 of the above-described modification may include, for example, a rectification diode provided at the output end of each of the DC/DC converter 30 and the RF amplifier 40 in place of the coil 51 and the capacitor 52 that are illustrated in FIG. 2.

The rectification diode provided at the output end of each of the DC/DC converter 30 and the RF amplifier 40 can also prevent the peak component of an envelope signal transmitted from the RF amplifier 40 from being transferred to the DC/DC converter 30 and a voltage transmitted from the DC/DC converter 30 from being transferred to the RF amplifier 40.

When the output signal of the DC/DC converter 30 is added to that of the RF amplifier 40 through the addition circuit 50 achieved through the rectification diodes, an inverted signal included in the output signal of the DC/DC converter 30 and a fluctuation component occurring in the addition circuit 50 cancel each other out.

Accordingly, the variation component of the output signal of the addition circuit 50 is cancelled out and a signal obtained by adding the peak component amplified through the RF amplifier 40 to the direct current component added through the DC/DC converter 30 is externally transmitted. The obtained signal has a waveform amplified to be similar to the waveform of an envelope signal transmitted from the envelope signal-output unit 10.

Accordingly, a driving voltage amplified to have a waveform similar to that of the envelope signal is transmitted to the transmission amplifier 60. Therefore, in the transmission amplifier 60, the envelope tracking is correctly performed for a main signal and a radio communication signal is externally transmitted in synchronization with the envelope signal.

When the addition circuit 50 includes the rectification diodes, it becomes possible to avoid the above-described transfer as is the case with the coil 51 and the capacitor 52 even though the variation component has a relatively high frequency.

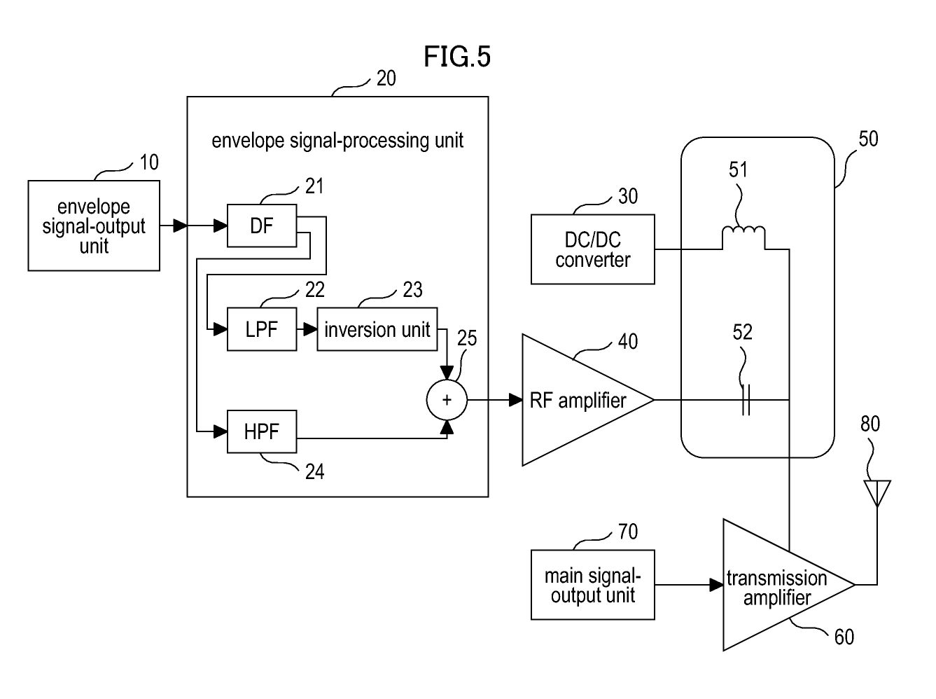

FIG. 5 illustrates a diagram illustrating the circuit configuration of a power circuit according to an embodiment of the present invention and a radio communication circuit including the power circuit. The power circuit of an embodiment and the radio communication circuit including the power circuit are different from those of an embodiment in that the envelope signal-processing unit 20 includes an addition circuit unit 25 and an output signal transmitted from the inversion unit 23 is not transmitted to the DC/DC converter 30, but to the addition circuit unit 25. Since the other components of the power circuit of the above-described embodiment and the radio communication circuit including the power circuit are the same as those of an embodiment, the same components are designated by the same reference numerals and the descriptions thereof are omitted.

In the power circuit of an embodiment and the radio communication circuit including the power circuit, an inverted signal transmitted from the inversion unit 23 is added to the peak component of an envelope signal transmitted from the HPF 24 through the addition circuit unit 25. Therefore, a voltage signal including the envelope signal and the inverted signal that are added to each other is externally transmitted from the addition circuit unit 25. The above-described voltage signal is amplified through the RF amplifier 40 and is transmitted to the addition circuit 50.

The DC/DC converter 30 of an embodiment is different from that of the above-described embodiment in that the inverted component is not transformed, but the direct voltage is transformed (boosted) and is externally transmitted. Therefore, the transformation rate of the DC/DC converter 30 may not be equal to the amplification rate of the RF amplifier 40. Further, a circuit configured to simply output a direct voltage may be provided in place of the DC/DC converter 30 described in an embodiment.

The addition circuit 50 provided in the power circuit of an embodiment adds the direct voltage transmitted from the DC/DC converter 30 to the voltage signal obtained by adding the envelope signal to the inverted signal, the voltage signal being transmitted from the RF amplifier 40, and the direct voltage and the voltage signal are externally transmitted. At that time, a fluctuation component occurs due to the alternating-current coupling attained by the capacitor 52. The fluctuation component and the inverted signal included in the output signal transmitted from the addition circuit 50 cancel each other out. Therefore, in the power circuit of an embodiment and the radio communication circuit including the power circuit, the output signal of the addition circuit 50 includes no fluctuation component, and a driving voltage having a waveform similar to the waveform (see FIG. 3A) of the envelope signal transmitted from the envelope signal-output unit 10 is externally transmitted as is the case with the driving voltage illustrated in FIG. 3G described in an embodiment.

Accordingly, the driving voltage having the waveform similar to that of the envelope signal is transmitted to the transmission amplifier 60. Therefore, in the transmission amplifier 60, the main signal is subjected to the envelope tracking and a radio communication signal is externally transmitted in synchronization with the envelope signal.

Thus, an embodiment allows for removing the variation component of a basic wave, the variation component occurring in the process of amplifying the envelope signal, and making the DC/DC converter 30 supply a direct voltage component of the driving voltage supplied to the transmission amplifier 60. Therefore, it becomes possible to provide a power circuit that can reduce the power loss based on the envelope tracking and a radio communication circuit including the power circuit.

Further, in an embodiment, the addition circuit 50 includes the coil 51 and the capacitor 52. However, without being limited to the above-described embodiment, the addition circuit 50 may not include the coil 51 and the capacitor 52.

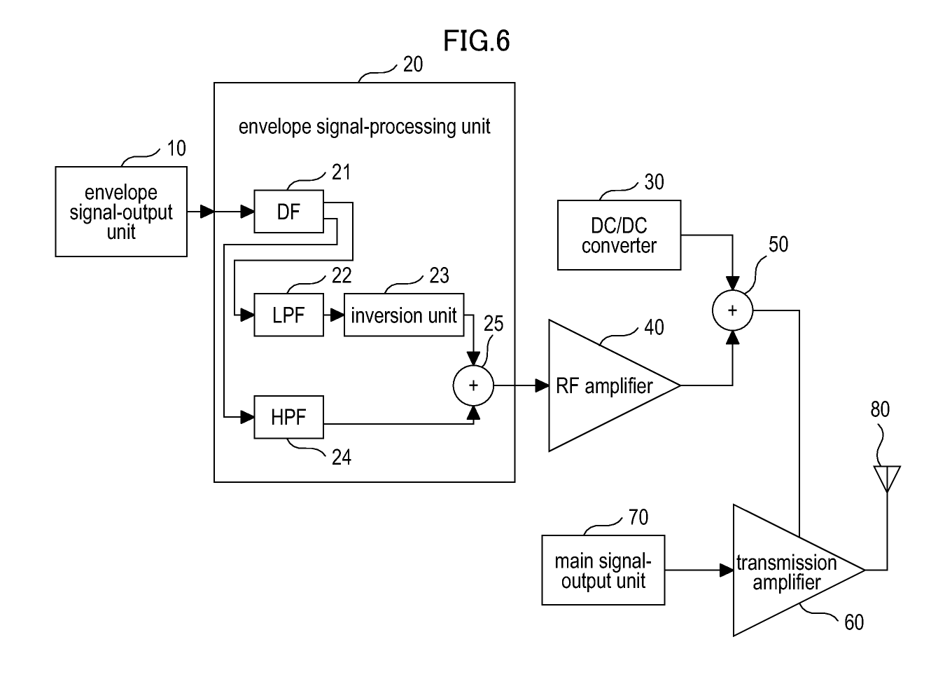

FIG. 6 illustrates a diagram illustrating the circuit configuration of a power circuit according to an exemplary modification of an embodiment and a radio communication circuit including the power circuit. The circuit configuration of the above-described modification is different from that illustrated in FIG. 5 in that the addition circuit 50 does not include the coil 51 and the capacitor 52, and is expressed as a block. The addition circuit 50 illustrated in FIG. 5 illustrates equivalent to that illustrated in FIG. 2 illustrating the exemplary modification of the above-described embodiment. The addition circuit 50 illustrated in FIG. 5 may include, for example, a rectification diode provided at the output end of each of the DC/DC converter 30 and the RF amplifier 40 in place of the coil 51 and the capacitor 52 that are illustrated in FIG. 5.

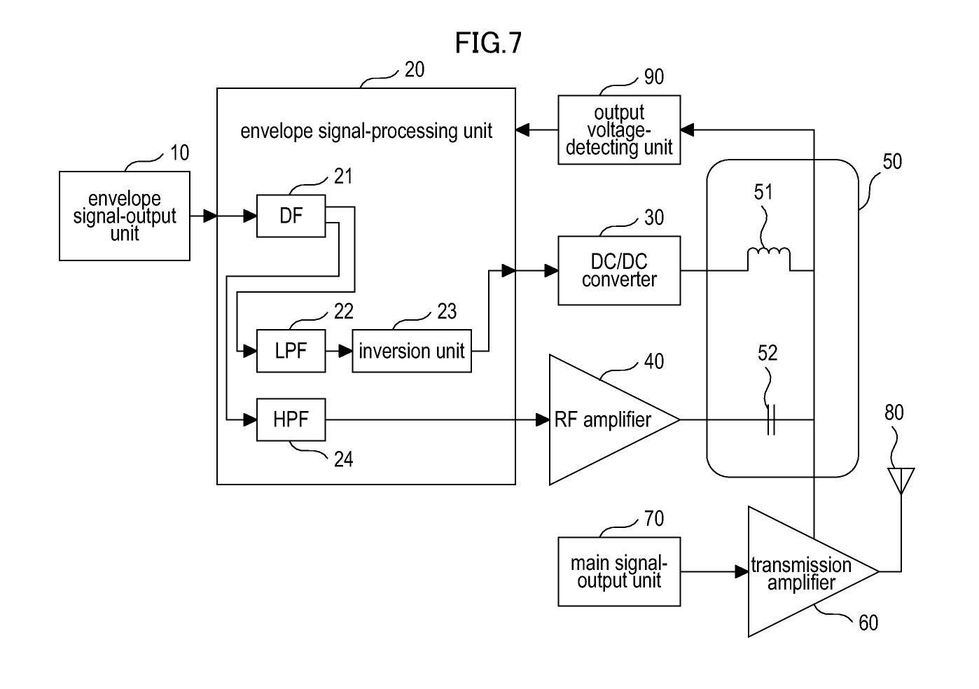

FIG. 7 illustrates a diagram illustrating the circuit configuration of a power circuit according to an embodiment of the present invention and a radio communication circuit including the power circuit. The power circuit of an embodiment and the radio communication circuit including the power circuit are different from those of the above-described embodiment in that an output voltage-detecting unit 90 configured to detect a driving voltage transmitted from the addition circuit 50 is provided and the envelope signal-processing unit 20 performs feedback control based on the driving voltage detected through the output voltage-detecting unit 90 to control the transformation rate of the DC/DC converter 30 and the amplification rate of the RF amplifier 40. Since the other components of the power circuit of an embodiment and the radio communication circuit including the power circuit are the same as those of the above-described embodiment, the same components are designated by the same reference numerals and the descriptions thereof are omitted.

As described above, the output voltage-detecting unit 90 detects the driving voltage transmitted from the addition circuit 50 and the detected driving voltage is transmitted to the envelope signal-processing unit 20.

The envelope signal-processing unit 20 calculates a difference between the driving voltage transmitted from the output voltage-detecting unit 90 and the envelope signal transmitted from the envelope signal-output unit 10, and controls the transformation rate of the DC/DC converter 30 and the amplification rate of the RF amplifier 40 to reduce the above-described difference (so that the transmitted envelope signal becomes similar to an envelope signal transmitted from the envelope signal-output unit 10).

Here, the driving voltage has a waveform similar to that of the envelope signal transmitted from the envelope signal-output unit 10. The driving voltage includes a direct voltage transmitted from the DC/DC converter 30 and a peak component amplified through the RF amplifier 40.

Therefore, the direct voltage and the amplified portion of the peak component should be deducted from the driving voltage to calculate the above-described difference through the envelope signal-processing unit 20. The difference may be calculated through, for example, an operational amplifier.

Thus, an embodiment allows for removing the variation component of a basic wave, the variation component occurring in the process of amplifying the envelope signal, and making the DC/DC converter 30 supply a direct voltage component of the driving voltage which shall be transmitted to the transmission amplifier 60. Therefore, it becomes possible to provide a power circuit that can reduce the power loss based on the envelope tracking and a radio communication circuit including the power circuit.

Further, the output voltage-detecting unit 90 configured to detect a driving voltage transmitted from the addition circuit 50 is provided and the envelope signal-processing unit 20 performs feedback control based on the driving voltage detected through the output voltage-detecting unit 90 to control the transformation rate of the DC/DC converter 30 and the amplification rate of the RF amplifier 40.

Therefore, even though initial variations and/or drifts occur in the driving voltages, the feedback control is performed to correct distortions. Consequently, the envelope tracking can be performed with increased precision.

Further, in the above-described embodiment, the addition circuit 50 includes the coil 51 and the capacitor 52. However, the addition circuit 50 may not include the coil 51 and the capacitor 52 without being limited to the above-described embodiment.

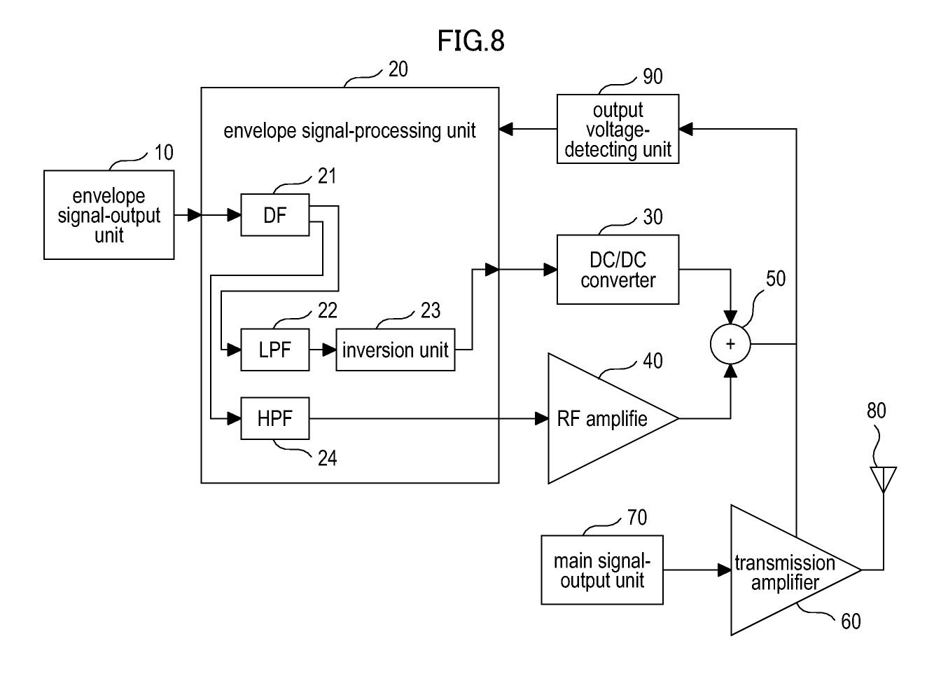

FIG. 8 illustrates a diagram illustrating the circuit configuration of a power circuit according to an exemplary modification of an embodiment and a radio communication circuit including the power circuit. The circuit configuration of the above-described modification is different from that of FIG. 7 in that the addition circuit 50 does not include the coil 51 and the capacitor 52, and is expressed as a block. The addition circuit 50 illustrated in FIG. 7 illustrates equivalent to that of FIG. 2 illustrating the exemplary modification of the above-described embodiment. The addition circuit 50 illustrated in FIG. 7 may include, for example, a rectification diode provided at the output end of each of the DC/DC converter 30 and the RF amplifier 40 in place of the coil 51 and the capacitor 52 that are illustrated in FIG. 5.

As described above, the power circuit of an embodiment and the radio communication circuit including the power circuit are achieved by adding the output voltage-detecting unit 90 to the power circuit of the above-described embodiment and the radio communication circuit including the power circuit (FIG. 2) so that the distortion of the driving voltage is corrected through the feedback control as illustrated in FIG. 7. Further, the power circuit of an embodiment and the radio communication circuit including the power circuit are achieved by adding the output voltage detecting unit 90 to the power circuit according to the exemplary modification of the above-described embodiment and the radio communication circuit including the power circuit (FIG. 4) so that the distortion of the driving voltage is corrected through the feedback control as illustrated in FIG. 8.

However, the feedback control of an embodiment may be achieved by adding the output voltage-detecting unit 90 to the power circuit of the above described embodiment, the power circuit being illustrated in each of FIGS. 5 and 6, and the radio communication circuit including the power circuit.

Thus, the power circuits according to the exemplary embodiments of the present invention and the radio communication circuits including the power circuits have been described. However, the present invention can be modified and/or changed in various ways without leaving the scope of the attached claims without being limited to the specifically disclosed embodiments.

The embodiments can be implemented in computing hardware (computing apparatus) and/or software, such as (in a non-limiting example) any computer that can store, retrieve, process and/or output data and/or communicate with other computers. The results produced can be displayed on a display of the computing hardware. A program/software implementing the embodiments may be recorded on computer-readable media comprising computer-readable recording media. The program/software implementing the embodiments may also be transmitted over transmission communication media. Examples of the computer-readable recording media include a magnetic recording apparatus, an optical disk, a magneto-optical disk, and/or a semiconductor memory (for example, RAM, ROM, etc.). Examples of the magnetic recording apparatus include a hard disk device (HDD), a flexible disk (FD), and a magnetic tape (MT). Examples of the optical disk include a DVD (Digital Versatile Disc), a DVD-RAM, a CD-ROM (Compact Disc—Read Only Memory), and a CD-R (Recordable)/RW. An example of communication media includes a carrier-wave signal.

Further, according to an aspect of the embodiments, any combinations of the described features, functions and/or operations can be provided.

Although a few embodiments have been illustrated and described, it would be appreciated by those skilled in the art that changes may be made in these embodiments without departing from the principles and spirit of the invention, the scope of which is defined in the claims and their equivalents.

What is claimed is:

1. A power circuit that includes an output circuit including an alternating current-coupling element and that supplies an output signal of the output circuit to an amplifier as a driving voltage, the power circuit comprising:
an envelope signal-extracting unit configured to extract an envelope signal from a carrier wave;
a simulation signal-waveform generating unit configured to generate a simulation signal including a fluctuation component occurring when the envelope signal is transmitted to the output circuit;
a fluctuation component-extracting unit configured to extract the fluctuation component included in the simulation signal; and
an inverted component-generating unit configured to generate an inverted component obtained by performing a phase inversion for the fluctuation component, and
wherein the fluctuation component occurring in the output circuit is canceled out through the inverted component.

2. The power circuit according to claim 1, comprising:
a peak component-extracting unit configured to extract a peak component from the simulation signal;
an amplifying unit configured to amplify the extracted peak component; and
a transformation unit configured to transform the inverted component, and
wherein the output circuit is configured to add the amplified peak component to the transformed inverted component and an amplification rate of the amplifying unit is equal to a transformation rate of the transformation unit.

3. The power circuit according to claim 1, comprising:
a peak component-extracting unit configured to extract a peak component from the simulation signal;
an addition unit configured to add an output signal of the peak component-extracting unit to an output signal of the inverted component-generating unit;
an amplifying unit configured to amplify an output signal of the addition unit; and
a direct current component-output unit configured to output a direct current component included in the driving voltage, and
wherein the output circuit is configured to add an output signal of the amplifying unit to a direct current component transmitted from the direct current component-output unit.

4. The power circuit according to claim 1, comprising:
a driving voltage-detecting unit configured to detect the driving voltage supplied to the amplifier; and
an adjusting unit configured to adjust the driving voltage so that the driving voltage detected through the driving voltage-detecting unit becomes similar to an envelope signal output from the envelope signal-extracting unit.

5. A radio communication circuit, comprising:
the power circuit according to claim 1; and
a final stage amplifier configured to output a signal in synchronization with the envelope signal, where the driving voltage is applied from the power circuit to the signal.

6. A method of controlling a power circuit, comprising:
removing a variation component occurring during a process of amplifying an envelope signal by performing a phase inversion for the variation component; and
externally transmitting a radio communication signal in synchronization with the envelope signal.
